(19) United States
(12) Patent Application Publication
(10) Pub. No.: US 2008/0062624 A1
(43) Pub. Date: Mar. 13, 2008

(54) Transformable Mobile Computing Device

(76) Inventors: Paul Regen, Felton, CA (US); Peter Garrett, Aptos, CA (US); Martin Boys, Redding, CA (US)

Correspondence Address: CENTRAL COAST PATENT AGENCY, INC, 3 HANGAR WAY SUITE D, WATSONVILLE, CA, 95076, US

(21) Appl. No.: 11/531,423

(22) Filed: Sep. 13, 2006

(51) Int. Cl. H05K 7/00

(52) U.S. Cl. 361/680; 361/681

(57) ABSTRACT

A mobile computing device has a first detachable input device, a second removable input device, and an elevation stand integral with the computing device. In use, the first and second input devices may be used to operate the mobile computing device while the input devices are in the detached or removed state and wherein the elevation stand may be leveraged to elevate the display of the mobile computing device.

### BACKGROUND OF THE INVENTION

1. Field of the Invention

The present invention is in the field of personal computing appliances including laptop and desktop computers and connected input devices. The invention pertains particularly to methods and apparatus for transforming a laptop computer for use as a desktop computer.

2. Discussion of the State of the Art

Of computing appliances, the most commonly used multitasking computers are desktop model computers. However, mobile computing has recently gained in the marketplace with provision of more affordable Laptop or notebook computers. Desktop and Laptop computers are very different from one another in terms of physical appropriations for housing the required electronics and input and display components for computing.

A typical desktop computer has a processor and a separate monitor that may be a flat screen monitor or a standard CRT monitor. External connectable audio speakers typically enable the sound for a desktop. Data input devices are also typically separate components of a desktop including an input keyboard, and an input mouse.

Laptop computers have all of the components of the desktop built into them. The monitor is a flat-panel type such as a liquid crystal display (LCD) screen that is housed within a display housing, which is hinged to the processor-housing component. The mouse input and keyboard input interfaces are integrated parts of the laptop computer. Both system types share common built-in interfaces like DVD/CD drives, universal serial bus (USB) ports, Ethernet data jack and telephone jack implementation is typically common to both systems, as well as card slot bays and other typical ports, lines in and lines out.

The system types described above are also used very differently. Most persons are somewhat familiar with operating a desktop. A separate keyboard and mouse input devices are used to operate the desktop computer and input data into the computer. The mouse typically rests on a mouse pad and the keyboard typically rests on a flat accessible surface such as a sliding keyboard stand on a computer desk. Most individuals are familiar with the point and click technology of the standard desktop mouse. Likewise, most are familiar with the standard keyboard arrangement and function keys of a desktop keyboard. The keyboard for a desktop tends to be large and easy to use with separate input key groups clearly defined as function keys, 10-keys, navigation keys, word keys, and number/symbol keys.

Although Laptops are gaining ground in the marketplace, many users find the input functions more difficult to master that those of the desktop. For example, instead of a mouse, a touch-pad is used with a laptop. The keyboard is built-in and therefore, organized in a smaller space with no real definable key groupings. Many of the function keys are toggled to provide more functions in the different modes. There is typically less space between Laptop keys and less height so data input tasks for the laptop may be more challenging for many. Most computer operators prefer larger desktop keyboards for faster and cleaner data input.

Some aftermarket electronics device makers have realized some reluctance among many users to fully embrace Laptop computers as main computing devices in the home or at the office. Some after market data input device alternatives are available for use with Laptop computers. More common are universal serial bus (USB) cabled mice so a Laptop user may avoid using the touch pad on the device. There are also aftermarket keyboards that connect to the Laptop via USB cable.

The inventor knows of a Laptop stand that is also available in the art and is used to elevate the Laptop monitor to a higher position for more convenient viewing. By placing the computer in a stand and then connecting the peripheral USB input devices, the laptop may be temporarily stationed and operated more like that of a standard desktop computer. Some problems exist with the after-market devices for Laptop type computers.

One problem is that USB mice and keyboards may commonly stop functioning during use with the Laptop requiring the user to unplug the USB device from the computer and then plug in the device in again so the operating system (OS) may re-recognize the device. Some devices with standard USB capabilities may not be entirely compatible with newer high-speed USB ports. Some require driver installation for proper recognition and function. Another issue is that Laptop stands that position a Laptop at an angle so the screen is much higher (like a desktop) have many moving parts that are prone to failure. Moreover the stands are not compact enough to conveniently store with the Laptop let alone the storage problems that exist with the other mentioned peripheral devices (USB mouse, USB keyboard). Therefore, these peripheral devices may be left in one location where the user intends to use the Laptop in a manner more like a desktop.

What is clearly needed in the art is a transformable mobile computing device that may be setup and used in the manner of a Laptop computer or a Desktop computer without requiring any externally maintained components that must be connected to external ports or the like. Such a transformable computing device would offer much more flexibility in personal preferences and in adjustment to various computing environments.

### SUMMARY OF THE INVENTION

According to an embodiment of the present invention, a mobile computing device is provided. The mobile computing device includes a first detachable input device, a second removable input device, and an elevation stand integrated with the computing device. In a preferred embodiment, the first and second input devices may be used to operate the mobile computing device while the input devices are in the detached or removed state and wherein the elevation stand may be leveraged to elevate the display of the mobile computing device.

In one embodiment, the mobile computing device is a notebook computer. In another embodiment, the mobile computing device is a personal digital assistant (PDA). In one embodiment, the first detachable input device is a keyboard and the second removable input device is a computer mouse. In one variation of this embodiment, the second removable input device is a touch pad removed by detaching the device and operable as a computer mouse while detached. In this embodiment, the computer mouse functions as a touch pad for the mobile computing device when not detached.

In one embodiment, the first detachable input device is a universal serial bus (USB) keyboard when attached to the mobile computing device and a wireless keyboard when detached from the mobile computing device. In one embodiment, the second removable input device is a USB touch pad when not removed from the mobile computing device and a wireless optical mouse when removed from the mobile computing device, the device removable by detaching the device.

In one embodiment, the mobile computing device includes a stored mouse pad. In a variation of this embodiment, the mouse pad is a USB hub and mouse pad combination attached to and detachable from the mobile computing device.

In one embodiment, the elevation stand includes a stand plate and a stand bar both swingedly attached to the mobile computing device. In this embodiment, the stand plate has at least one foot for seating the stand bar to assume a position of elevation.

In one embodiment inclusive of a stored mouse pad, the mouse pad is removed from a storage position in the display housing of the mobile computing device. In another embodiment, the mouse pad is stored in a compartment provided on a base housing of the mobile computing device. In one embodiment, the mobile computing device has an organic light emitting diode (OLED) display.

According to another aspect of the present invention, a method is provided for transforming a mobile computing device for operation as a desktop computing device, the mobile device including a detachable keyboard, a removable mouse, and one or more integral elevation stand components. The method includes the acts (a) detaching the keyboard from the mobile computing device, (b) removing or detaching the mouse from the mobile computing device, (c) swinging out the elevation stand components from their integral positions on the mobile computing device, (d) adjoining the stand elements together at a position of elevation for the mobile computing device, and (e) using the input devices to operate the mobile computing device.

In one aspect, in act (a), the keyboard is a USB keyboard when attached and a wireless keyboard when detached. In this aspect, the mobile computing device is one of a notebook computing device or a PDA computing device. In one aspect, in act (b), the mouse functions as a touch pad when not removed from the computing device and wherein the mouse functions as an optical mouse when removed from the mobile computing device. In another aspect, in act (c), the mouse is an optical mouse stored in a compartment provided on the mobile computing device.

### BRIEF DESCRIPTION OF THE DRAWING FIGURES

FIG. 1 is a plan view of a mobile transformable computing device according to an embodiment of the present invention.

FIG. 2 is a perspective view of a mobile transformable computing device illustrating a version of elevation stand according to an embodiment of the present invention.

FIG. 3 is a perspective view of a mobile transformable computing device illustrating an elevation stand according to another embodiment of the present invention.

FIG. 4 is a bottom view of the dual mode input device of FIG. 1 according to an embodiment of the present invention.

FIG. 5 is an elevation view of the dual mode device of FIG. 1.

FIG. 6 is a perspective view of the mobile transformable computing device of FIG. 1 illustrating the elevation stand configuration of FIG. 1.

FIG. 7 is a process flow chart illustrating acts for transforming a mobile computing device to be used as a desktop computing device according to an embodiment of the present invention.

### DETAILED DESCRIPTION

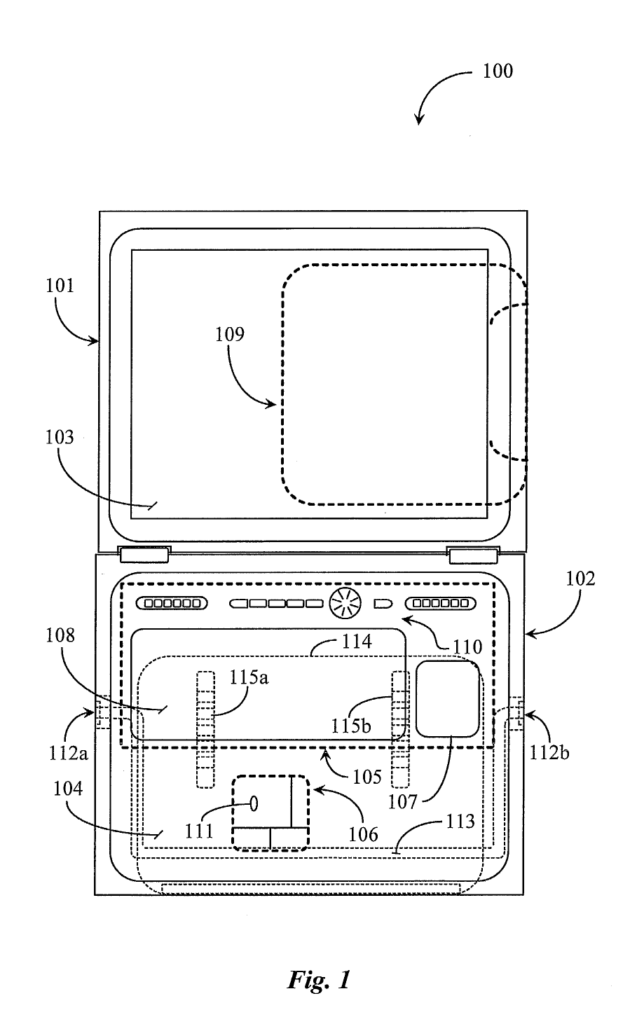

FIG. 1 is a plan view of a mobile transformable computing device 100 according to an embodiment of the present invention. Device 100 is provided in the familiar form of a laptop or notebook-computing device using standard materials and manufacturing processes. As such, device 100 has a processor base housing 102 and a flip-up monitor or user interface (UT) screen housing 101 in this example. Base housing 102 includes a housing face or surface 104. Housing 102 contains and supports the processor circuitry, hard drive, removable drives, ports, card slots, line-in jacks, line out jacks, input circuitry, and other components known to accompany a notebook or laptop computing device. The exact number and description of the elements may depend according to the version or brand of computing device as some laptops have features that others do not have and so on. It may be assumed in this example that at least all of the basic features of a notebook or laptop computer are present in this example.

UT screen housing 101 contains all of the required components for enabling a UI graphics monitor or screen 103. Screen 103 may be any type of notebook screen including but not limited to a liquid crystal display (LCD) screen, high-definition LCD or Plasma LCD, or display screens using newer and emerging technologies.

Unlike a typical notebook-computing device, device 100 has an ejectable keyboard input device 105 provided thereto. Keyboard 105 contains all of the function keys required to fully operate and interact with the features of computing device 100 and any applications and programs available on the device. Keyboard 105 is adapted with added controls 110 that control a variety of features and functions including but not limited to accessing the Internet, controlling volume, launching email applications, and the like. Keyboard 105 may be manufactured using a polymer-based material or other standard materials used for making keyboards. It may be assembled in similar fashion as resident keyboards accept that it has a base portion that is not contiguous with the computer base.

Keyboard 105 may be physically ejected from computing device 100 and used as an external keyboard input device that may communicate with computing device 100 via universal serial port (USB) or some wireless communication technology such as, infrared or Bluetooth™ technology. A keyboard bay (not illustrated) is strategically provided in face 104 of processor housing 102 for retaining keyboard input device 105 when it is used as a notebook keyboard. It is noted herein that removable or ejectable components of device 100 are illustrated with broken line boundaries in this example.

In one embodiment of the present invention, keyboard device 105 is capable of emitting light through specially designed keys on the keyboard so that the keys are highly visible during low light situations ranging from inadequate lighting to complete darkness. In this embodiment, keyboard 105 may be caused to illuminate via a provided power control button included in a control panel area 110 on the keyboard. Illuminating the keyboard may also be accomplished with a keystroke action of one or more keys on the keyboard. In this embodiment, keyboard 105 may have its own power supply (battery) and may be caused to illuminate when seated within base housing 102 or when ejected and used as an external keyboard.

It is noted herein that the key layout or arrangement of keys on a keyboard is typically different depending on whether the keyboard is designed for use with a desktop computer or with a notebook computer. In this example, the keys arrangement for keyboard 105 may be of either type of arrangement. In one embodiment, the keys are arranged in configuration for use as a desktop keyboard for convenience of the user. In this example, keyboard 105 is key-arranged as a desktop keyboard having clearly separated key groupings 108 and 107.

Key group 108 includes the alphanumeric, symbol, and function keys used during normal typing. Key group 107 includes the 10-key number and function keys. Keyboard 105 may be smaller in size that a standard external desktop keyboard as may be required to fit in a smaller footprint for use in notebook mode, or when the keyboard is retained into the keyboard bay of computing device 100. It should be noted however, that the exact design and layout of the keys and controls of keyboard 105 are not particularly relevant to the present invention.

In one embodiment, keyboard 105 may, when plugged into its bay on computing device 100 operate as a USB keyboard device. In this embodiment, a USB port may be strategically provided on the back surface of keyboard 105 and a male USB plug may be strategically provided within the bay. In this embodiment, keyboard 105 may be oriented to the bay aligning the USB interface and causing the USB interface to become active when the board is urged down into the bay. Since the USB interface will be provided at manufacture for both the computer and the keyboard, maximum compatibility may be ensured for error free operation unlike a typical peripheral USB keyboard. In this embodiment the USB board is the main and only board.

One or more ejection mechanisms or devices (not illustrated) may be strategically located within the keyboard bay with one or more user interface buttons (ejection button) located on and accessible from surface 104, perhaps conveniently adjacent to the seated keyboard. The mechanisms may be spring activated or lever activated mechanisms. The ejection means shall be sufficiently strong to “unplug” the USB interface in this embodiment. Once unplugged, a wireless mode of communication may be automatically activated for external keyboard input communication with computing device 100.

In another embodiment, keyboard 105 may operate in a continuously wireless mode when docked to device 100 and when used as an external keyboard input device. In this embodiment there are no USB interfaces. A simple friction connector may be provided in the bay to keep the keyboard charged and operating whenever lap top device 100 is powered on. It is important to note that the example of USB for connecting keyboard device for communication while docked or not is just one of many possible utilities that might be considered. Other examples of possible connection interfaces include serial port, Firewire, or other standard or proprietary pin, plug, or friction connector interfaces.

In another embodiment, the USB interface is not broken when keyboard 105 is ejected. Rather, a reasonable long retractable USB ribbon cable may be provided that extends USB connectivity for use as a USB external keyboard. In one embodiment as described above, USB is not used at all to port keyboard 105 to computing device 100. Instead, keyboard 105 may communicate using a wireless or in both docked mode and in external mode. There are many possibilities.

It is noted herein that typically, USB interfaces are external interfaces. The provision of a USB interfacing component in a location that is physically internal to a device like lap top 100, for example, as opposed to the typical external ports enables a new concept of internal USB porting for connecting various components of a device wherein the components may be removed from the device when not in use or to be used externally from the device.

Computing device 100 has a unique dual-mode input device 106 that is also ejectable from computing device 100. Input device 106 is a notebook touchpad when it is not ejected from computing device 100. However, when input device is ejected from computing device 100, it may be turned over for external use as an optical input mouse. Input device 106 is seated into a dock or bay (not illustrated) provided within surface 104 of base housing 102. When input device 106 is docked to computing device 106, it operates as a notebook touchpad having a touch surface for movement detection, scrolling, and right and left click screens. In optical mouse mode, the input device may be used externally with a mouse pad. An optical light emitting diode 111 is visible on input device 106 on the side used as a touchpad surface. More detail about dual mode input device 106 is provided later in this specification.

Computing device 100 has a removable or ejectable mouse pad 109 provided thereto and adapted for use as a “mousing” surface for input device 106 when used as an optical mouse. Mouse pad 109 is thin enough to be stored in a mouse pad bay (not illustrated) provided within the UI screen housing 101 behind screen 103 in this example. Mouse pad 109 may be a standard mouse pad or it may be a USB hub/mouse pad combination device without departing from the spirit and scope of the present invention. In the latter case, mouse pad 109 may be USB cabled through the mouse pad bay it is stored in, the cable routed down through housing 101 behind screen 103 into the appropriate PCI interface in the motherboard of device 100 supported within base housing 102.

In one embodiment, mouse pad 109 may be stored in some other compartment. For example, a mouse pad compartment may be provided within base 102 and mouse pad 109 may be rolled up and stored inside the provided compartment. There are other possible storage locations as well. The inventor illustrates a compartment behind screen 103 in housing 101 because there is space there that may not typically be used or filled in a normal notebook computer.

Computing device 100 has a built-in elevation stand that may be used to elevate the computer from a normal flat-seated position to an elevated angle position so that the screen of the computing device may be raised in elevation more to eye level comparable to that of most desktop computer monitors. The stand includes a base plate 114 (broken line boundary) that is swingedly attached via hinge or similar hardware to the back surface of the compartment on the rear side of housing 102. When the stand is closed, base plate 114 is flush with the back surface of computer base housing 102.

Base plate 114 has two stand feet 115a and 115b provide thereon and strategically located thereon for the purpose of seating a spring bar 113 that may be retained in a compartment adapted for the purpose provided in base 1202 beneath base plate 1 14. Base plate 114 may include a snap mechanism (not illustrated) for retaining the component in a closed position when not in use.

Feet 115a and 115b may be molded together with base plate 114 as a single contiguous part. In another embodiment, they may be assembled to base plate 114 using a nut and bolt or other mechanical assembly hardware. In one embodiment, feet 115a and 115b may be glued onto or snapped onto plate 114 in their required orientation.

Feet 115a and 115b are arranged in parallel and aligned with each other and spaced apart to function as bar feet or stops. Each foot has multiple bar seats formed therein and cross-aligned horizontally to one another so that multiple angles of elevation of the notebook may be achieved as desired. Feet 115a and 115b are located on the inside surface of plate 114 and fit into special recesses provided in base housing 102, the recesses adapted to house them when plate 114 is closed. Plate 114 and feet 115a and 115b may be formed of a durable lightweight polymer typically used to manufacture computer housings and the like.

Spring bar 113 is rotably attached to base housing 102 in special boots 112a and 112b located on either side and on the inside of base housing 102. Boots 112a and 112b may be formed into housing 102 as part of the housing molding process. Relief is provided through the back surface of base housing 102 so that spring bar 113 may be freely swung out from its retained position. In one embodiment, spring bar 113 is made of spring steel and may be physically attached and removed from boots 112a and 112b by compressing the bar inward at both ends to dislodge it from boots 112a and 112b. In another embodiment it is installed permanently and cannot be removed from housing 102 without removing the back surface plate of the housing.

To set up computing device 100 at a desired angle above a flat surface, a user first un-latches base plate 114 from the back of device 100 and allows it to swing out while raising the device. The user then grasps spring bar 113 (retained under plate 114) and swings it outward axially about boots 112a and 112b. The user may then rest the horizontal portion of spring bar 113 onto feet 115a and 115b in the desired pair of bar seats provided. Keyboard 105, mouse pad 109, and touch pad 106 may be ejected from device 100 before elevating the device or after the device is elevated. In this way, device 100 may be transformed for use as a desktop computer. Elevating computing device 100 at an angle above a flat surface simply enables screen 103 to be viewed at an elevation more particular to a desktop monitor providing comfort for the user.

It will be apparent to one with skill in the art that by integrating the components into the mobile computing device instead of providing a separate stand and peripheral input devices, more flexibility is afforded to the user who may now use the mobile device as a desktop device more conveniently and in more locations. Likewise, no extra provisions like an accessory bag or added compartments to a computer carrying case are required. Computing device 100 with all of the components does not take up any more space than a normal notebook.

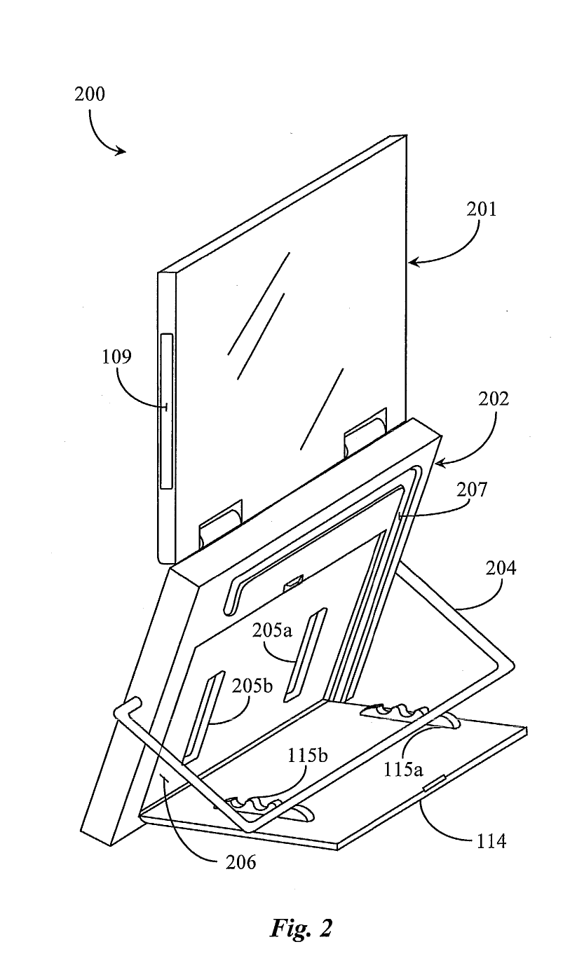

FIG. 2 is a perspective view of a mobile transformable computing device 200 illustrating a version of an integrated elevation stand according to another embodiment of the present invention. Mobile computing device 200 is analogous to device 100 described above accept for the way the elevation stand is integrated.

Computing device 200 has a computer base housing 202 and a computer screen housing 201. Housing 201 is hingedly attached to base 202 in a fashion known for notebook computers. Eject able mouse pad 109 is visible recessed into screen housing 201. Base housing 202 includes stand base plate 114 in substantially the same configuration as previously described. Feet 115a and 115b are visible in this example. When plate 114 is closed, feet 115a and 115b fit into recess 205a and recess 205b.

The back surface of plate 114 is flush with the back surface of housing 202 when closed. Compartment 206 is deep enough to accommodate the thickness of plate 114. It is noted herein that standard notebook components like the processor, fan, battery, and so on may be accessed through removable plates (not shown) in the same fashion as with normal notebook computers. The provision of recesses for accommodating the stand components may be orchestrated with standard component locations and accessibility requirements of those components for maintenance at the time of design and manufacture of the computing device. The space requirements and provisions are a matter of design and may be accomplished economically without sacrifice of normal component access and maintenance functions.

In this example, a spring bar 204 is provided as a detachable and separate component of the stand configuration for device 200. Bar 204 attaches on the outside of computer base housing 202 in boots provided strategically for the purpose. When not being used to elevate device 200, bar 204 may be retained within a bar-retention groove 207 formed on the back surface of base housing 202. Bar groove 207 has a width and depth dimension sufficiently large enough to accommodate bar 204 such that the outer surface of the bar does not extend past the back surface of computer base housing 202. Retention groove 207 may include one or more snap retainers for retaining bar 204 within the groove when the mobile computing device 200 is being transported or used as a mobile device.

To elevate computing device 200 at an angle above a flat surface according to this embodiment, a user may first remove spring bar 204 from retention groove 207. Then the user may un-latch base plate 114 and allow it to swing out while raising device 200. The user may then seat one side of bar 204 into the provided boot and then the user may expand the bar by pulling in a direction opposite the seated side of the bar to seat the other side into the opposite boot. The user may then seat the horizontal portion of the bar into the desired bar seat pair on feet 115a and 115b to obtain the desired elevation angle. As described further above, the mouse pad, touch pad and the keyboard may be ejected before or after setting up the stand and seating it to the desired angle.

In both of the embodiments described with respect to FIGS. 1 and 2, the stand components are carried with the computing device and do not have to be separately ported. The computing device of the present invention therefore has no greater footprint then a normal notebook computer not enhanced with an integral stand and may be transported using standard carrying cases or bags in the same fashion as a normal notebook.

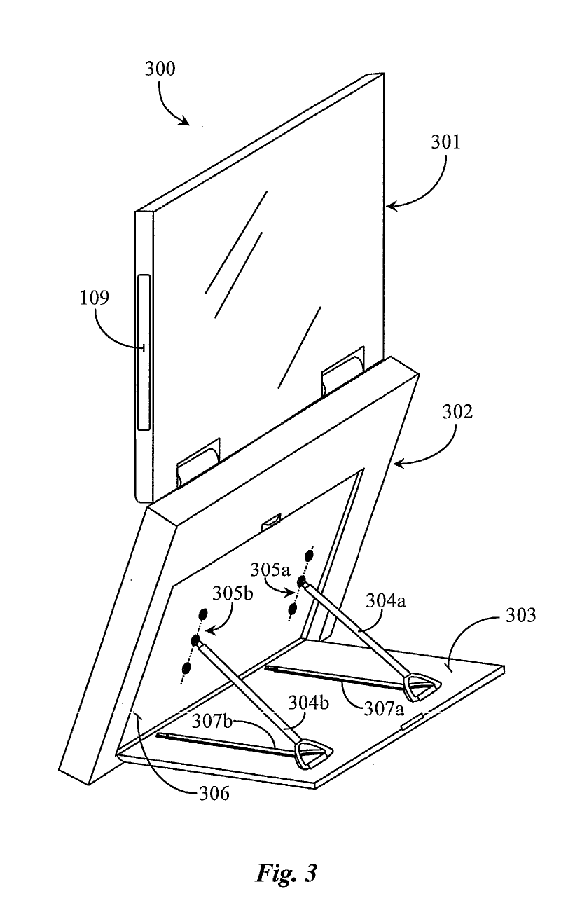

FIG. 3 is a perspective view of a mobile transformable computing device 300 illustrating an integral elevation stand according to yet another embodiment of the present invention. Mobile computing device 300 has a screen housing 301 and a computer base housing 302 similar to the previous embodiments described. Mouse pad 109 is visible in this embodiment retained within screen housing 301. In this example, there is no spring bar or bar feet required. A base plate 303 is provided and adapted as a swing-out plate retained within a recess 306 provided in the back surface of base housing 302. Base plate 303 is hingedly mounted to one side of recess 306 to enable it to be swung out from housing 302 in similar fashion as described further above.

In this example, plate 303 has two elevation rods 304a and 304b hinged thereto and retained in rod retention recesses 307a and 307b provided in the inside surface of plate 303. Rod 304a and rod 304b have a hook, loop or other similar form on one end to accommodate attachment via hinge at positions corresponding with the rod-retention recesses such that when plate 303 is closed, rod 304a and rod 304b reside within recess 307a and recess 307b respectively. The exposed surface of recess 306 has two aligned and equally spaced hole patterns 305a and 305b provided therein and adapted to present positions to retain the free ends of rods 304a and 304b when used to elevate computing device 300 at an angle above a flat surface. In this example, there are 3 holes per pattern, the holes vertically aligned in each pattern. The patterns are parallel to one another with respect to each hole in a pattern aligned with an opposing hole located in the other pattern.

To elevate computing device for use as a desktop computer in this embodiment, a user lifts device 300 and un-latches plate 303 letting the plate swing out. The user then grasps one of the retained rods and pulls it up aligning the rod free end with one of the holes in the corresponding hole pattern. The same sequence is repeated with the other rod. Preferably the same hole is selected in each pattern for ensuring a stable angled position. In this example, the center hole is selected in each pattern. It is noted herein that there may be more holes in a pattern than just 3 as illustrated in this example.

One with skill in the art will recognize that there are other elevation stand design options available to the inventor than the options illustrated in this example. In one embodiment, telescopic rods may be used. In another embodiment, base plate 303 takes up less space by way of strategic cut outs leaving minimum area to function as an actual stand base. One with skill in the art will appreciate that there may also be provisions provided in base plate 303 like cutouts for enabling access to certain components without requiring that base plate 303 be opened. In one embodiment, base plate 303 and other similar plates described previously may be manufactured from a heat-sink material to help dissipate heat generated by the computer processor.

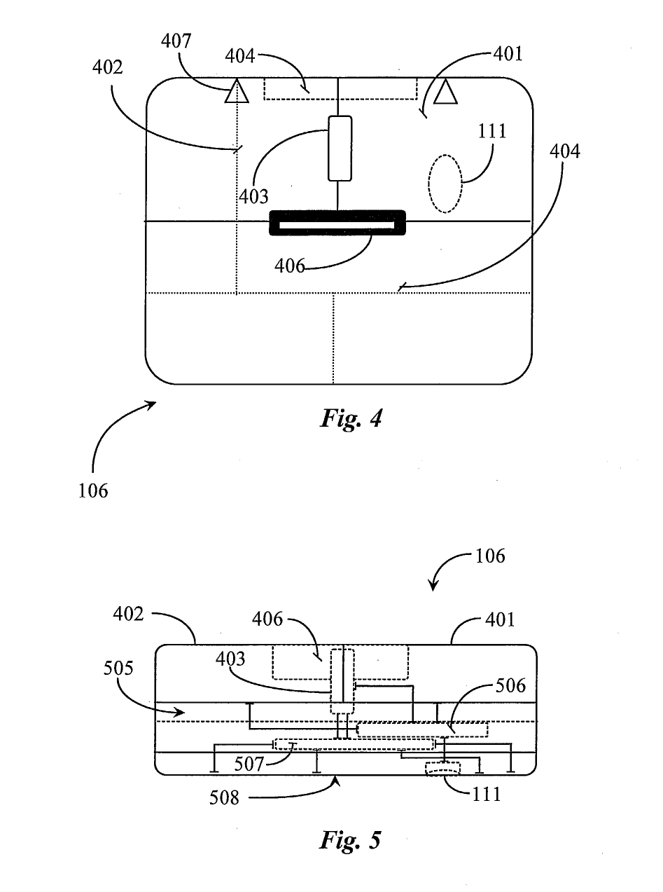

FIG. 4 is a bottom view of dual mode input device 106 of FIG. 1 according to an embodiment of the present invention. Input device 106 functions as a touch pad when docked to the host computing device. However, when it is ejected from the host, it may be turned over and used as an optical mouse. In this view of input device 106, the optical mouse features are visible. Input device 106 has a right click pad 401 and a left click pad 402. LED 111 is now on the underside side of device 106 when used as an optical mouse.

A scroll wheel 403 used commonly for toggling page-scrolling functionality when working in an application is provided in this example. Scroll wheel 403 may provided within a formed depression between click pads 401 and 402 so that the upper surface of the wheel does not protrude above the surface of the optical mouse side of the input device. A hand rest portion 404 of the mouse is not functional but provides the familiar ergonomic resting surface for the hand of a user operating the device. The touch pad feature on the opposite side of device 106 in this view is illustrated using broken line.

Input device 106 may have a USB interface 406 provided thereto and recessed underneath the surface of the device to enable docking to the host computing device for the touch pad function. USB interface 406 may be a male portion of the interface and the port or female portion may reside at the bottom center of the touch pad compartment. In this way, when device 106 is plugged into the USB port by pressing the device down into the cavity on the host, the USB connection engages and the touch pad is recognized. In another embodiment a connector interface such as a USB or other serial interface connector may be oriented on the side of the device and on the cavity. In this embodiment, the cavity may be provided slightly longer that the touchpad device to allow for insertion into the cavity and subsequent coupling of the serial connection.

In the optical mouse mode, device 106 may have wireless communication circuitry 404 provided thereto and adapted to become active when the USB connection is disengaged. The host recognizes the wireless signal and the mouse may be operated wirelessly. Infrared, Bluetooth™, or other wireless communication format may be used. Device 106 may have position orientation arrows stamped, formed, or otherwise provided thereon for the purpose of informing a user the correct orientation for re-engaging device 106 to the host to function as a USB touch pad. The touch pad features are visible in this example as areas separated by broken lines. For example, there is typically a touch pad navigation window for controlling the mouse input and selection. There is typically a right click pad and a left click pad. There is also typically a page scrolling touch pad section. The 4 areas are visible in FIG. 1 and in this example. Other variant arrangements of components are possible without departing from the spirit and scope of the present invention.

FIG. 5 is an elevation view of input device 106 of FIG. 1. Device 106 has a separation cavity 505 provided substantially in the middle of the device and extending the breadth and width of the device. The separation cavity is adapted to space the opposing components apart and to allow a specific range of motion for the click pad functions of both the touch pad interface side 508 of device 106 and for the optical mouse side of the input device.

Input device 106 has two microcontroller components, a microcontroller 506 for controlling mouse function, and a microcontroller 507 for controlling touch pad function. Each of the features of input device 106 may be bussed or wired to the appropriate microcontrollers for normal use. In this example, wheel 403, click pads 401 and 402 are logically bussed to microcontroller 506, which registers the motion and notes the functions activated and communicates those to the host via wireless technology through circuitry 404. The touch pad components are logically bussed to processor 507, which in turn registers the motion and notes the functions activated and communicates those to the host through the USB interface formed within the touch pad compartment on the host.

Only one of the dual modes may be active at any one time. Therefore in one embodiment, only one microcontroller is required. It is important that the profile of device 106 remain thin enough to be accommodated within the limits of the mobile computing device base housing. In one embodiment, the device is thinner than the thickness of the host base housing and sits in the compartment or cavity and does not protrude above the surface level of the computer based. However, in another embodiment a certain degree of elevation for the touch pad platform of the host computer may be tolerated. Therefore, device 106 may have an overall thickness greater than the thickness of the host computer base housing.

The provision of this unique dual mode input device to a host mobile computer provides a convenient and logical mechanism for adding an optical mouse function to the host device without requiring an additional compartment or cavity that is not already occupied by some other component. When the host device is in desktop mode, the touch pad is not utilized in any event whether there is an extra mouse or not. The combination of an optical mouse and a touch pad interface into a single input device is a unique and novel way to enable the transformation of the host from a mobile notebook to a useable desktop computing device.

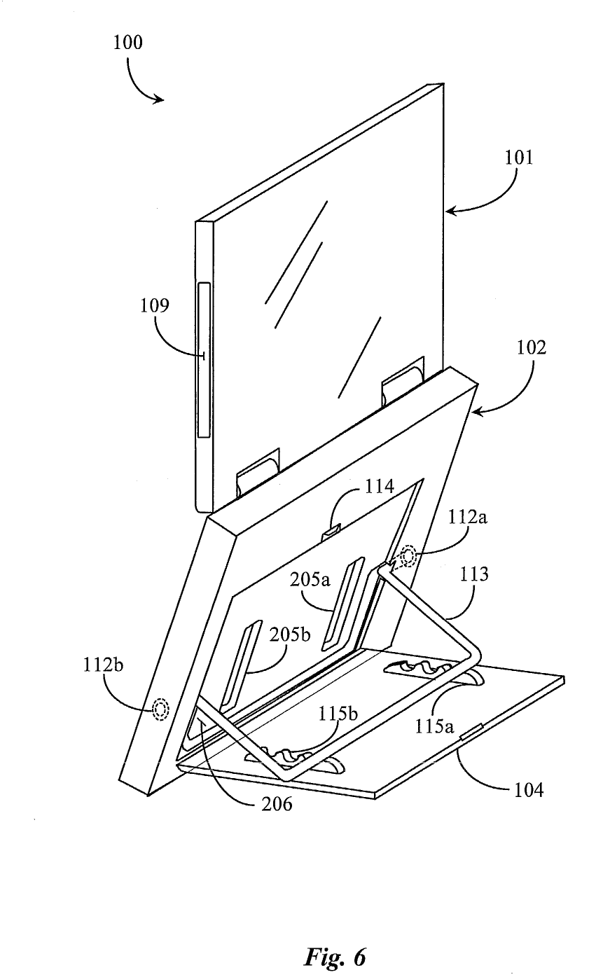

FIG. 6 is a perspective view of mobile transformable computing device 100 of FIG. 1 illustrating the elevation stand configuration of FIG. 1. In this view, the implementation of the integral elevation stand is more clearly seen. Spring bar 113 fits snugly into a recess adapted for the purpose and located beneath base plate 114. The spring bar fits into boots 112b and 112a and may freely swing about to function as a stand bar. Bar 113 is resting in bar seats on feet 115a and 115b locking the stand into a position of elevation. With screen housing 101 open fully, the display screen is raised to that height comparable to a desktop monitor resting on a computer desk.

FIG. 7 is a process flow chart illustrating acts 700 for transforming a mobile computing device to be used as a desktop computing device according to an embodiment of the present invention. At act 701 a user operating a transformable mobile computing device makes a decision about whether to transform the device for use in the fashion of a desktop computing device. If at act 701 the user decides not to transform the computing device, then at step 702 the user operates the computing device as a mobile computing device or notebook. It is noted herein that the mobile computing device need not be booted in this embodiment to be transformed. Upon boot of the computing device in either mode, the input mechanisms (keyboard and touch pad/mouse) are recognized by the operating system in either state of docked or ejected.

The process resolves back to act 701 at user discretion. If at act 701, the user decides to transform the computing device, then at act 703, the user may eject the keyboard from the mobile computing device. In this act, one or more ejection mechanisms may be provided for the user to manipulate to accomplish the task. The keyboard may be docked to an internal USB port such that upon ejection, the operating system recognizes the ejected state and looks for a wireless signal emitted by the keyboard when not in use as a USB keyboard. Therefore, if the computing device is booted and running at the time of act 703, the keyboard may be immediately recognized by the operating system and activated for normal keyboard function in wireless mode.

In one embodiment, the keyboard remains a USB connected board and ejection thereof from the host simply disengages the keyboard from the bay but does not break the USB connection. In this embodiment, there may be a USB cable connecting the ejected board to a USB port located on the computing device in a strategic manner such that the slack USB cable may be stored out of sight under the keyboard when it is docked to the computing device.

At act 704, the user may eject the touch pad/mouse input device from the computing device. At act 704, ejection of the touch pad/mouse device may break a USB connection that is active for using the touch pad features of the device. In this case, ejection state is recognized by the host and the host and a wireless connection as described above may be automatically activated and recognized by the host. In another embodiment the USB connection between the computing device and the touch pad/mouse is not broken, rather the touch pad features may be turned off automatically to enable the optical mouse features of the device. As described further above, turning the device over completely from the docked position may operate the mouse features.

At act 705, the user may eject the mouse pad. This act is not required in order to specifically practice the present invention as the user may supply an external mouse pad instead of using the docked pad. At this point if the computing device has been booted and is running, the ejected components may be used in the fashion of a desktop computer to enable interaction with the computer.

At act 706, the user lifts the computing device up from the surface it is resting on and un-latches the computer stand plate on the rear side of the computer base housing. While still providing lift for the computing device, the user allows the stand plate to swing out as previously described above. At act 708, the user un-seats the spring bar from a groove provided for the purpose of retaining the bar in a strategic location beneath the plate.

At act 709, while still providing lift to the computing device, the user may swing the spring bar out and into position for seating. At act 710, while still providing lift to the computing device, the user rests the horizontal portion of the bar against the bar seats of the feet of the stand plate. At this point the computing device is elevated at a desired angle. At act 711, the user may position the display screen of the computing device for optimum viewing. The computing device may now be operated as a desktop computing device using a peripheral keyboard and a peripheral mouse and wherein the screen of the computing device is elevated to eye level with a seated user.

To transform back to a mobile computing device, a reverse sequence of acts 700 may be performed whether the computing device has been booted and is running or whether it is on stand by or off. It is important to note herein that the exact sequence of acts 700 may vary considerably without departing from the spirit and scope of the present invention. For example, the computing device may first be elevated before any input devices are ejected from the computing device. Likewise the order of ejection of components may vary according to user discretion.

It should be noted herein and one with skill in the art of electronic display technology will understand the methods and apparatus of transforming a mobile computing device to be used in a manner like that of a desktop computer are not limited to mobile computing devices having standard state-of-art display screens. In one embodiment of the resent invention the mobile transformable computing device has a display screen manufactured using polymeric light emitting diode technology or (PLED). Another known term for this type of display screen is organic light emitting diode (OLED). In this emerging technology it is possible to print a display screen using ink-jet technologies to print the polymer chains onto glass or flexible plastic substrates. The flexibility feature may give rise to display screens that do not flip open like in traditional mobile computing devices. These newer screen may be rolled up into a device and then pulled out to form the display screen.

In the above embodiment, providing a bay or pocket elsewhere on the computing device may enable the provision of a mouse pad like mouse pad 109, as there may not be an operable display housing to support the display screen in a PLED embodiment. In any case the integral stand of the mobile computing device remains viable, as a method to raise the display more to the user's eye level as described the exact type of display is not relevant to the invention.

The present invention may be practiced using some of or all of the components described herein without departing from the spirit and scope. More commonly, notebook computers may be manufactured with the capability to be transformed for use in the fashion of a desktop computing device. However, the invention is not limited to laptop or notebook computers. Varieties of handheld computing appliances use keyboards and have interfaces for other input devices. Therefore, a version of the invention may be practiced for those appliances newly manufactured with the capabilities of the invention. The methods and apparatus of the present invention should be limited only by the following claims.

What is claimed is:

1. A mobile computing device comprising:
a first detachable input device;
a second removable input device; and
an elevation stand integrated with the computing device;
characterized in that the first and second input devices may be used to operate the mobile computing device while the input devices are in the detached or removed state and wherein the elevation stand may be leveraged to elevate the display of the mobile computing device.

2. The mobile computing device of claim 1 embodying a notebook computer.

3. The mobile computing device of claim 1 embodying a personal digital assistant (PDA).

4. The mobile computing device of claim 1, wherein the first detachable input device is a keyboard and the second removable input device is a computer mouse.

5. The mobile computing device of claim 1, wherein the second removable input device is a touch pad removed by detaching the device and operable as a computer mouse while detached.

6. The mobile computing device of claim 5, wherein the computer mouse functions as a touch pad for the mobile computing device when not detached.

7. The mobile computing device of claim 1, wherein the first detachable input device is a universal serial bus (USB) keyboard when attached to the mobile computing device and a wireless keyboard when detached from the mobile computing device.

8. The mobile computing device of claim 1, wherein the second removable input device is a USB touch pad when not removed from the mobile computing device and a wireless optical mouse when removed from the mobile computing device, the device removable by detaching the device.

9. The mobile computing device of claim 1, further comprising a stored mouse pad.

10. The mobile computing device of claim 9, wherein the mouse pad is a USB hub and mouse pad combination attached to and detachable from the mobile computing device.

11. The mobile computing device of claim 1, wherein the elevation stand includes a stand plate and a stand bar both swingedly attached to the mobile computing device.

12. The mobile computing device of claim 11, the stand plate has at least one foot for seating the stand bar to assume a position of elevation.

13. The mobile computing device of claim 9, wherein the mouse pad is removed from a storage position in the display housing of the mobile computing device.

14. The mobile device of claim 9, wherein the mouse pad is stored in a compartment provided on a base housing of the mobile computing device.

15. The mobile computing device of claim 1, wherein the mobile computing device has an organic light emitting diode (OLED) display.

16. A method for transforming a mobile computing device for operation as a desktop computing device, the mobile device including a detachable keyboard, a removable mouse, and one or more integral elevation stand components comprising the acts:
(a) detaching the keyboard from the mobile computing device;
(b) removing or detaching the mouse from the mobile computing device;
(c) swinging out the elevation stand components from their integral positions on the mobile computing device;
(d) adjoining the stand elements together at a position of elevation for the mobile computing device; and
(e) using the input devices to operate the mobile computing device.

17. The method of claim 16, wherein in act (a), the keyboard is a USB keyboard when attached and a wireless keyboard when detached.

18. The method of claim 16, wherein in act (a), the mobile computing device is one of a notebook computing device or a PDA computing device.

19. The method of claim 16, wherein in act (b), the mouse functions as a touch pad when not removed from the computing device and wherein the mouse functions as an optical mouse when removed from the mobile computing device.

20. The method of claim 16, wherein in act (c), the mouse is an optical mouse stored in a compartment provided on the mobile computing device.
